(19) United States
(12) Patent Application Publication
(10) Pub. No.: US 2023/0087626 A1
(43) Pub. Date: Mar. 23, 2023

(54) RECYCLABLE AND SELF-COOLING SOLAR PANELS

(71) Applicant: Higher Dimension Materials, Inc., St. Paul, MN (US)

(72) Inventor: Young-Hwa Kim, Hudson, WI (US)

(21) Appl. No.: 17/795,988

(22) PCT Filed: Jan. 28, 2021
(86) PCT No.: PCT/US2021/015373

§ 371 Date: Nov. 10, 2022

Related U.S. Application Data
(60) Provisional application No. 62/968,460, filed on Jan. 31, 2020.
(60) Provisional application No. 63/062,866, filed on Aug. 7, 2020.

(51) Int. Cl. H02S 30/10; H02S 40/42; H01L 31/048

(52) U.S. Cl. CPC H02S 30/10; H01L 31/0488; H02S 40/425; H02S 20/10

(57) ABSTRACT

Some examples of the solar panels described herein mitigate wind resistance problems in comparison to conventional solar panels by introducing porosity to the panel that permits the free flow of air, rain, and sunlight through the panel. The flow of air dramatically reduces the wind resistance allowing the panel to be installed substantially above ground level, freeing the land under the panels to be used for other purposes. Additional benefits are that rain and sunlight can reach the ground under the panels to sustain plant and animal life without the permanent environmental damage associated with the implementation of traditional solar panels in solar energy farms. In addition, the solar panels described herein can be made of materials that have higher heat conductivity and are recyclable or reusable.

### CROSS-REFERENCE TO RELATED APPLICATIONS

This application claims the benefit of U.S. Provisional Application Serial No. 62/968,460, filed Jan. 31, 2020, and U.S. Provisional Application Serial No. 63/062,866, filed Aug. 7, 2020. The disclosures of the prior applications are considered part of (and are incorporated by reference in) the disclosure of this application.

### BACKGROUND

### 1. Technical Field

In some examples, the disclosure relates to solar panels that convert sunlight into electricity. In some examples, the solar panels described herein are constructed to mitigate solar panel heating, to reduce wind loading, and to reduce the environmental impact at the solar panel’s end of life.

### 2. Background Information

Solar power is more affordable, accessible, and prevalent than ever before. In the U.S., installations have grown 35-fold since 2008 to an estimated 62.5 gigawatts (GW) today. This is enough capacity to power the equivalent of 12 million average American homes. Since the beginning of 2014, the average cost of solar photovoltaic (PV) panels has dropped nearly 50%.

The expected growth in solar over the years of 2019 to 2024 is expected to exceed 70 GW, and will be dominated by commercial and industrial applications. This is because economies of scale combined with better alignment of PV panel supply and electricity demand enable more self-consumption and bigger savings on electricity bills in the commercial and industrial sectors. As a result, millions of solar panels each year will be manufactured and installed at large solar farms all over the world. The average service life of solar panels is about 20 to 25 years.

### SUMMARY

There are four persistent, major, technical, and environmental problems with conventional solar panels.

The first problem is that solar farms destroy environments, lands, and ecological systems. Large scale conventional solar farms using conventional solar panels occupy millions of acres of flat land, forest lands, desert lands, grasslands, and farmlands. Builders of large-scale solar farms cut trees in forests, bulldoze lands, and destroy flora and fauna of vast areas of natural green lands. Damaged ‘bare’ land without trees and vegetation cannot absorb and hold waters from heavy rains. The damaged lands may contribute to massive and uncontrollable floods and landslides. Economically active and fertile farmlands are destroyed for large-scale solar farms.

The second problem is that at end of life, these millions of solar panels are discarded into landfills. The service life of a modern solar panel is about 20 to 25 years. Each year, many millions of large pieces of expired solar panels are discarded somewhere on land. A solar panel is mostly made of non-degrading and non-decomposing materials. When these expired solar panels are buried under ground, the large solar panels block flow of underground water and diffusion of oxygen in soils, kill underground flora and fauna, and pollute underground water with traces of harmful chemicals which leak from expired (and often physically broken) solar panels. Some embodiments of the invention disclosed herein incorporate materials that are readily recyclable and need not find their way into massive landfills.

The third problem is the high temperature of conventional solar cells. Solar cell efficiency is the electrical power delivered by a solar cell divided by the product of the solar irradiance (the power of the sunlight incident on the solar cell) times the area of the cell. Commercially available solar modules are only about 20% efficient in converting sunlight into electricity. That means that 80% of the energy of the incident sunlight is converted to heat. The only heat dissipation mechanisms for a conventional panel are the transfer of heat from the Tedlar backing and the glass front of the panel to air. The thermal conductivity of glass is only 1.7 W/(mK) and that of Tedlar is only 0.16 W/(mK). This results in solar panels getting very hot. Even in subzero ambient temperature below 0° C., the temperature on a solar panel can rise to above 50° C. in strong sunlight. During the hot summer season in tropical regions where the ambient temperature goes up to about 40° C., the temperature on the solar panel rises to 80° C. or even more. It is well known that efficiency of a solar panel reduces as much as 30% at 85° C. as compared to its efficiency at 25° C. In addition, the heat damage the photovoltaic silicon wafers, irreversibly shortens the service life of the solar panels by several years. On a windless, hot, and clear-sky day, thousands of densely packed solar panels of a large-scale solar farm will generate a huge amount heat, and the heat will raise the air temperature of the solar farm. This rise in the air temperature can cause damage to flora and fauna on the ground of the solar farm and its surroundings.

As described further below, some examples of the solar panels disclosed herein mitigate the heat dissipation problem, by transferring the heat generated by solar cells to a heat dissipating backsheet. The backsheet forms a pan that holds a plurality of solar cells that are electrically insulated from the backsheet while still permitting heat transfer. Such a solar panel module may be referred to herein as an “YK-Module.”

YK-Modules are attached to a heat dissipating frame that maintains an empty space between adjacent YK-modules. The space permits the free flow of air, rain, snow, particulates, and sunlight through the array of YK-modules in a direction substantially perpendicular to the plane of the YK-modules. An array of YK-Modules may be referred to herein as an “YK-Panel.”

YK-Panels can be connected to one another to form arrays with spaces between adjacent YK-Panels (analogous with the spaces between YK-Modules within the YK-Panels). The spaces between YK-Panels permit the free flow of air, rain, snow, particulates, and sunlight through the array of YK-Panels in a direction substantially perpendicular to the plane of the YK-Panels.

A fourth problem with conventional solar panels is wind resistance which results in a major stress for the land area that must be used for large-scale solar farms. Modern conventional solar panels are large, e.g., occupying two to several square meters. These large and flat solar panels are typically installed about 1 to 2 meters above the ground. Due to the immense wind pressure (wind load) these large flat solar panels may receive in a strong gusty wind (e.g., 30 meter per second or more of wind speed), these large solar panels cannot practically be installed higher above the ground. Therefore, the land under solar panels cannot be economically used for other purposes. For the same reason, these large solar panels cannot be installed well above treetops of a forest. Accordingly, one must cut down trees of forest and bulldoze the land in order to build a solar farm. Moreover, many lands such as farmlands, land along riverbanks, narrow and long land along highways, and steep hills of mountains cannot be used for conventional solar farms. In summary, construction of large solar farms destroys large areas of environmentally important or economically producing farmlands or ranches. In a country that is covered over 70% with mountains, flat lands are precious.

Some examples of the solar panels described herein mitigate the wind resistance problems described above by introducing porosity to the panel (open spaces within the panel). The porosity permits the free flow of air, rain, and sunlight through the panel. The flow of air dramatically reduces the wind resistance allowing the panel to be installed substantially above ground level, freeing the land under the panels to be used for other purposes. Additional benefits are that rain and sunlight can reach the ground under the panels to sustain plant and animal life without the permanent environmental damage associated with the implementation of traditional solar panels in solar energy farms.

In one aspect, this disclose is directed to solar panel system (“YK-Panel”) configured to convert sunlight to electrical energy. The YK-Panel includes two or more YK-Modules. Each YK-Module of the two or more YK-Modules includes a tray comprising a heat-conductive substrate and a solar cell assembly contained within the tray. The solar cell assembly includes: (i) a solar cell, (ii) an encapsulant, and (iii) a transparent cover. The solar cell is contained within the encapsulant. A bottom surface of the encapsulant faces the tray and a top surface of the encapsulant faces the cover. The YK-Panel also includes a frame assembly attached to each tray of the two or more YK-Modules to provide structural support to the two or more YK-Modules. Open space is defined between adjacent YK-Modules of the two or more YK-Modules.

Such a YK-Panel may optionally include one or more of the following features. The open space may total at least 10% of a total area of the YK-Panel. The open space may total at least 20% of a total area of the YK-Panel. The open space may total 10% to 30% of a total area of the YK-Panel. The YK-Panel may also include one or more interconnectors extending laterally from each tray of the two or more YK-Modules. The one or more interconnectors may connect adjacent trays of the two or more YK-Modules. The frame may include multiple ribs that interlock with each other and with the two or more YK-Modules. The multiple ribs may include tabs that extend through respective slots defined by each tray of two or more YK-Modules. In some embodiments, the two or more YK-Modules may comprise twenty-four YK-Modules.

This disclosure is also directed to a solar farm system comprising a plurality of the YK-Panels. In some embodiments, the two or more of the YK-Panels are elevated at least three meters above ground level. In some embodiments, the two or more of the YK-Panels are elevated at least five meters above the ground level.

### BRIEF DESCRIPTION OF THE FIGURES

FIG. 1 is a perspective view of an example YK-Panel comprised of an array of four (4) YK-Modules each with a single solar cell contained in each.

FIG. 2 is a perspective view of the YK-Panel of FIG. 1 that is attached to a frame of interlocking ribs.

FIG. 3a is a perspective view of an example completed YK-Panel with 24 YK-Modules attached to its frame.

FIG. 3b is an underside perspective view of the completed YK-Panel of FIG. 3a.

FIG. 4 is a cross-sectional view showing an example construction of a solar-active YK-Module.

FIG. 5 is a perspective view of a top side of an example YK-Module that has four photovoltaic cells in accordance with some embodiments.

FIG. 6a is a perspective view of a top side of an example YK-Panel with six YK-Modules.

FIG. 6b is an underside perspective view of the YK-Panel of FIG. 6a.

FIG. 7a is a graph that illustrates, for porous plates sealed in wind tunnels that force all air flow through the pores in the plate, the wind load factor decreases with the square of the porosity.

FIG. 7b shows an example porous perforated sheet material.

FIG. 7c shows another example porous perforated sheet material.

FIG. 8 are schematic diagrams depicting the principle that porosity allows air to flow through a panel, limiting the turbulence behind the panel.

FIG. 9 is a graph that illustrates a comparison of wind tunnel wind load coefficient for radar antennae of two different porosities.

FIG. 10a is a perspective view of an example H-Type HelioTower.

FIG. 10b is a perspective view of an example S-Type HelioTower.

FIG. 10c is a perspective view of an example T-Type HelioTower.

FIG. 11 is a perspective view showing that substantial sunlight reaches the ground under an example H-Type HelioTower with YK-Panels in comparison to a conventional solar panel.

FIG. 12 is a perspective view of a solar farm comprised of example H-Type HelioTowers with YK-Panels that enables a dual use of land (e.g., electricity power generation and agriculture).

FIG. 13 illustrates a row of example T-Type HelioTowers along a boundary of a rice field.

FIG. 14 illustrates a line of example T-Type HelioTowers along a fence of a manufacturing plant.

FIG. 15 illustrates an example S-Type HelioTower at a town square.

FIG. 16 illustrates an example YK-Panel and a conventional solar panel being tested on roof top.

FIG. 17 is a graph depicting a comparison of the temperature of an example YK-Panel with that of a conventional solar panel.

FIG. 18a is a perspective view of an example support skeleton of an example T-Type HelioTower that can support a plurality of YK-Panels that are elevated well above the ground and occupy small land area.

FIG. 18b is a perspective view of a completed T-Type HelioTower of FIG. 18a, showing multiple YK-Panels mounted on the tower.

### DETAILED DESCRIPTION

The solar panel systems described herein address the above-described four major problems associated with large solar farms of conventional solar panels. The solar panel systems described herein can use existing photovoltaic materials such as silicon wafers, and new photovoltaic materials can be incorporated into new types of solar modules and solar panels so that the new solar modules and solar panels will become instruments for solution of the four major problems. For convenience, we will call the newly invented solar modules described herein, “YK-Modules,” and the newly invented solar panels described herein, “YK-Panels.”

The YK-Panel includes an array of two or more YK-Modules. In some embodiments, each YK-Module is a single solar cell comprised of a heat-conductive substrate that is designed to contain or otherwise support solar cells, such as silicon wafers, and other requisite materials that convert sunlight into electricity. The YK-Module is designed to be attached to a frame that can support a plurality of YK-Modules. Such a plurality of YK-Modules are electrically interconnected one to another to form a YK-Panel. The electrical interconnections of the YK-Modules in the YK-Panel form a circuit that can deliver electricity from the YK-Panel to provide power to an external load.

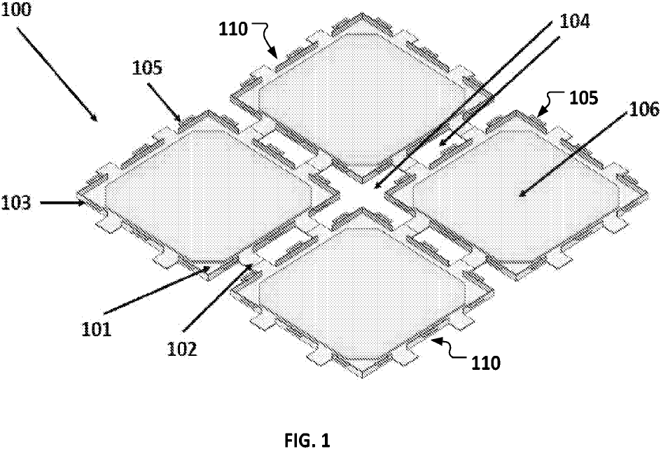

A first example embodiment is shown in FIGS. 1-4. In FIG. 1, an example YK-Panel 100 is comprised of an array of four (4) YK-Modules 110. A single YK-Module 110 has a substrate that is comprised of a flat and thin (e.g., 0.5 mm to 2 mm) sheet of aluminum that is formed into a tray 101 that has raised edges 103, slotted tabs 105 and interconnectors 102 that connect one YK-Module 110 to adjacent YK-Modules 110.

Each tray 101 contains one crystalline silicon wafer 106 capable of converting sunlight into electricity. A unique feature of this YK-Panel 100 is that the YK-Modules 110 are separated from one another by empty/open space gaps 104 that permit the free flow of air (wind), sunlight, and water (e.g., rainwater) through the YK-Panel 100 in a direction substantially perpendicular to the plane of the YK-Panel 100.

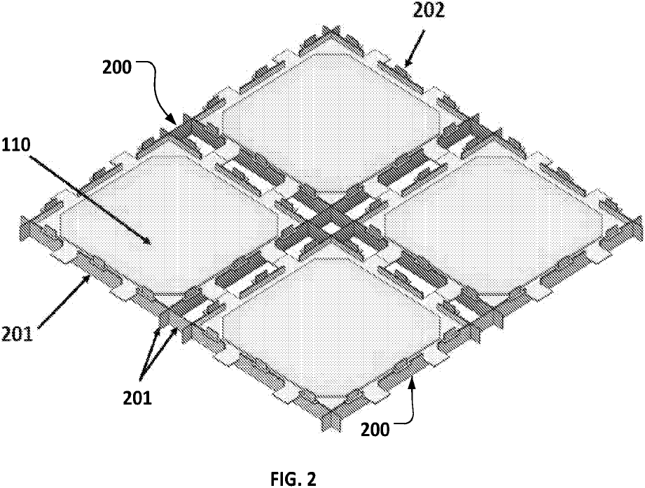

FIG. 2 shows the embodiment of the YK-Panel 100 (FIG. 1) wherein the YK-Modules 110 are attached to a frame 200. In this non-limiting example embodiment, the frame 200 is comprised of ribs 201 interlocked with one another to provide a stable support for the YK-Modules 110. Vertical tabs 202 of the ribs 201 pass through slots in the YK-Module tabs 105. The vertical tabs 202 are then bent over the slotted tabs 105 on the YK-Modules 110 to securely attach the YK-Modules 110 to the frame 200 without solder, welds, or glue.

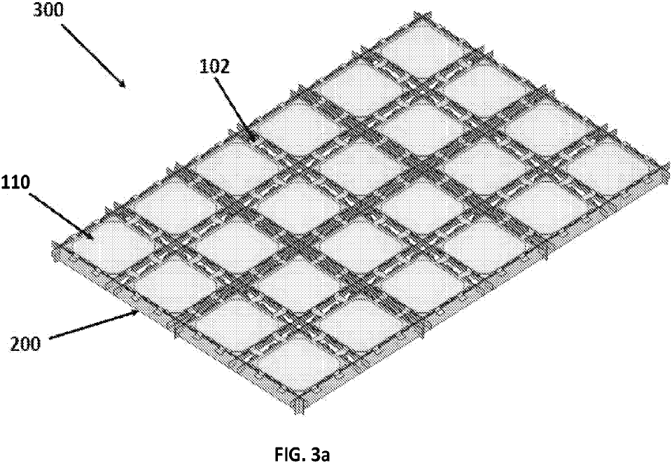

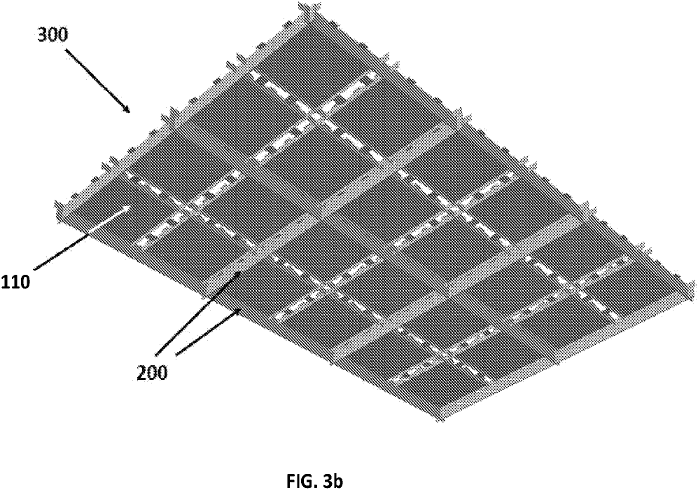

FIG. 3a shows a top perspective view of an example YK-Panel 300 with multiple YK-Modules 110 attached to the frame 200. The depicted YK-Panel 300 has twenty-four YK-Modules 110. In some embodiments, the YK-Panels described herein can have any other desired number of YK-Modules 110 such as, but not limited to one, two, three, four, five, six, eight, ten, twelve, fourteen, sixteen, eighteen, twenty, twenty-two, twenty-eight, thirty, thirty-two, thirty-six, or more than thirty-six, without limitation.

Individual solar cells that are contained in the YK-Modules 110 are electrically connected to one another by electrical conductors supported by the YK-Module interconnectors 102 shown in FIG. 1.

FIG. 3b shows an underside view of the YK-Panel 300 of FIG. 3a. The design pays special attention to providing structures for large heat dissipation of the YK-Panel 300 via to the large surface areas of both the heat conducting substrate of the YK-Module 110 and to the material of the frame 200. Note the total large surface area of the frame ribs 201. The large surface area of the heat-conducting material comprising the frame 200 and the substrate of the YK-Modules 110 ensures efficient cooling of the YK-Panel 300.

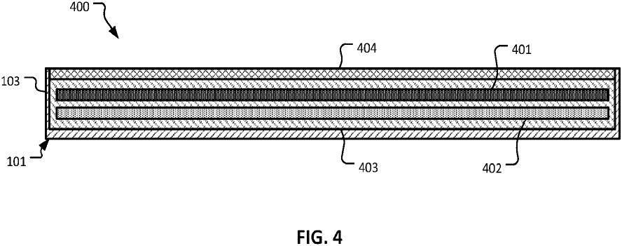

FIG. 4 shows a schematic cross-sectional view of an example solar-active YK-Module 400. The YK-Module 400 includes a YK-Module tray 101 that contains a solar cell and other materials required to convert sunlight into electricity. The YK-Module tray 101 has a raised edge 103 (also see FIG. 1) to form a tray sufficiently tall to contain a solar cell 401, an electrical insulator 402, an encapsulant 403, and a transparent glass cover 404. A bottom surface of the encapsulant 403 faces the tray 101, and a top surface of the encapsulant 403 faces the cover 404.

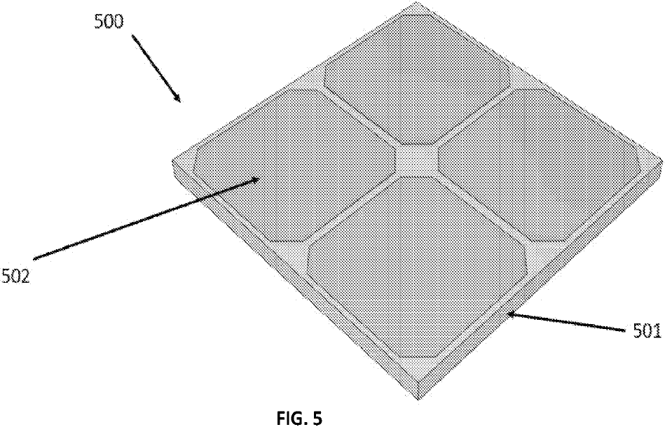

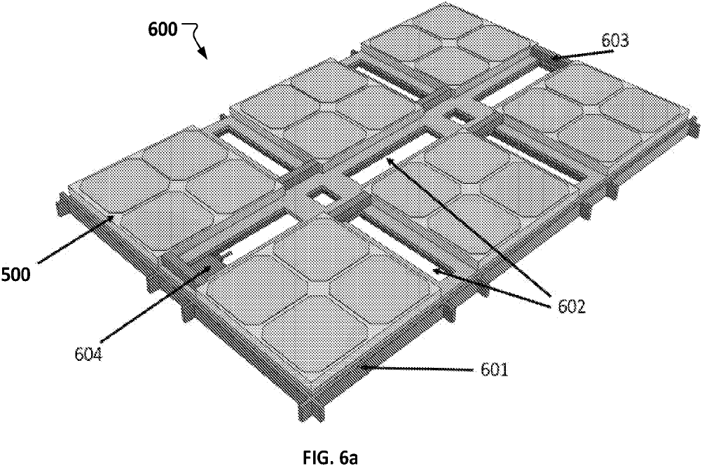

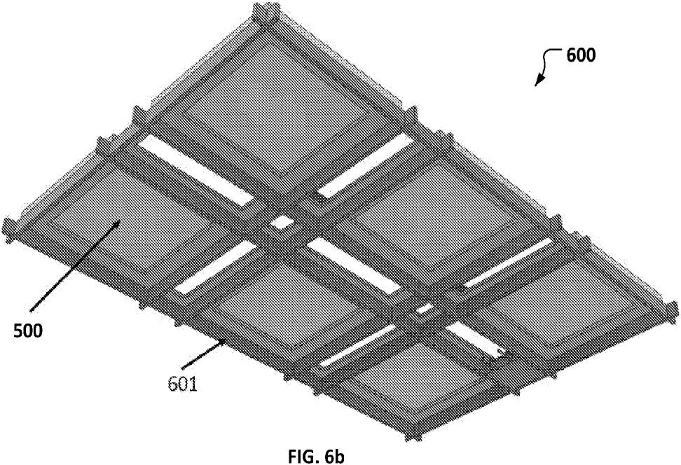

A second example embodiment of the solar panel systems described herein is shown in FIG. 5-6b. FIG. 5 shows a top perspective view of an example YK-Module 500 that has four photovoltaic cells 502 that can convert sunlight to electricity. While this example YK-Module 500 includes four photovoltaic cells 502, any number of photovoltaic cells 502 can be combined to create YK-Modules of other scales.

In some embodiments, the photovoltaic cells 502 are electrically connected to one another (electrical connection not shown) by a standard tabbing and stringing circuit common to the solar energy industry. In this particular example, the edges of the top surface of the heat-conductive substrate 501 are raised to provide a dish to hold photovoltaic cells and other materials required to form a working solar module.

FIGS. 6a and 6b illustrate an example YK-Panel 600. FIG. 6a shows the top side of the YK-Panel 600. The YK-Panel 600 includes six YK-Modules 500 mounted to a frame 601. The YK-Modules 500 are separated from one another by empty gaps 602 that permit air, rainwater and sunlight to pass through the YK-Panel 600.

Electrical connections between the YK-Modules 500 are established through the channels 603 that culminate in a junction box 604. The YK-Panel 600 is connected to other YK-Panels or to an electrical load by means of the junction box 604.

The frame 601 both supports the YK-Modules 500 and provides a ribbed structure with a large-surface-area that can transfer heat from the YK-Modules 500 to the surrounding atmosphere. The design pays special attention to providing structures for large heat dissipation of the YK-Panel 600 via to the large surface areas of both the heat conducting substrate of the YK-Module 500 and to the material of the frame 601.

In FIG. 6b, a bottom view of the ribbed structure of the frame 601 is shown. FIG. 6b also illustrates that the bottom surface of the YK-Modules 500 permit attachment of the YK-Modules 500 to the frame 601. The YK-Modules 500 can be attached to the frame 601 by any convenient means such as soldering, welding, gluing, or by a purely mechanical means such as those described above in reference to FIGS. 2 and 3. Any suitable alternate means of attachment of the YK-Modules 500 to the frame 601 may be used to meet end product requirements.

In some embodiments of the YK-Panels 100/300/600 described above, the heat conductive substrate of the tray and/or frame is aluminum that has a thickness of 0.5 mm to 2 mm. The choice of aluminum and the thickness thereof are not limiting. That is, other materials and other thicknesses of materials may be used. For example, the substrate may be a heat conductive metal such as copper, steel, titanium, or magnesium. Moreover, the substrate need not be a metal at all, it could be chosen to be a polymer such as a polyester, or acrylic that is appropriately filled with a ceramic material such as boron nitride or aluminum nitride to enhance the thermal conductivity. The choice of material for the substrate and its thickness may require trade-offs in the thermal conductivity versus other factors such as electrical resistance, strength and weight. Such considerations will need to be considered depending on the specifications for the final product.

In some embodiments described herein, the photovoltaic cells are single crystal silicon wafers, but this choice is not limiting. Other choices for photovoltaic cells include, but are not limited to, amorphous silicon wafers, thin film constructions, CdTe, or perovskite materials. Any type of photovoltaic cell appropriate to the final application can be used.

In some embodiments, the encapsulant used is EVA (Ethyl Vinyl Acetate), but other types of encapsulating materials such as silicone rubber, polyurethanes, or epoxies can also be used. The electrical insulator is an optional component of the construction. If the encapsulant is something like EVA that has only a moderate electrical resistance, an insulator such as fiberglass, nylon, polyimide, a ceramic-filled polyester, or a ceramic-filled acrylic. These choices are not limiting to the scope of the disclosure. For a ceramic-filled plastic as the insulator, materials such as boron nitride or aluminum nitride can be used as the filler ceramic. The insulator should be chosen to have high electrical resistance but also be a good heat conductor. The above-mentioned materials have those characteristics.

The unique features of the YK-Modules and YK-Panels described herein address the four problems associated with conventional solar panels mentioned above. For example, the photovoltaic silicon wafer (or other photovoltaic materials) is encapsulated in a flat and shallow tray made of aluminum sheet (or metal alloy sheet). As shown in FIG. 4, the entire surface of the photovoltaic silicon wafer (except the glass-covered sunlight-receiving top surface), is covered by the aluminum sheet (or metal sheet) of the tray that has a high degree of thermal conductivity.

Another unique feature of the YK-Modules and YK-Panels described herein is that the YK-Modules are attached to the aluminum (or metal alloy) frame of YK-Panel in such a way that each YK-Module is separated from its neighboring YK-Modules with empty gaps between them. The empty gaps let air, rainwater, and sunlight pass through the YK-Panel. For example, FIGS. 1 and 6a shows the empty gaps 104/602 between neighboring single, solar-cell YK-Modules.

These unique features of the YK-Modules and YK-Panels can address the four problems described above that are associated with conventional solar panels as follows.

The first problem (the destruction of environments, lands, and ecological systems) and the fourth problem (wind resistance or loading) are strongly tied to one another. Traditional solar panels are large flat panels that must bear immense wind pressure in strong and gusty winds. To prevent the panels from being destroyed, the panels are typically mounted within one or two meters of the ground surface. Unfortunately, the close proximity of the panels to the ground in the solar farms and the fact that rain, sunlight, and gentle breezes cannot reach the ground beneath the conventional solar panels causes permanent damage to the land underneath the panels. Builders of solar farms cut trees, bulldoze land, and destroy flora and fauna to install the panels for a solar farm. As a result, the land under the panels cannot be used for agricultural or commercial purposes. Ultimately, the land is destroyed by erosion, and by the growth of noxious weeds and undesirable insects and other animals.

The YK-Panels described herein mitigate the problems of wind resistance and ecological damage by allowing air, rain and sunlight to freely pass through YK-Panels via its empty gaps between adjacent YK-Modules.

Regarding wind loading, a conventional solar panel does not have any empty gaps (open space) and, therefore, wind cannot pass through it. The surface area of a conventional solar panel is several square meters, and there are no holes or empty gaps in conventional solar panels, through which air can pass. Therefore, the total force that wind pressure (wind load) exerts on a large conventional solar panel in a strong gusty wind (e.g., 30 meters per second of wind speed) is very large (e.g., on the order of several hundred to a few thousand kilograms). Wind load on a YK-Panel with its empty gaps which cover about 10% to 30% of the total surface of the YK-Panel is significantly less than the wind load on a conventional solar panel of the same size. The fraction of total area represented by the gaps or open space is called “porosity.”

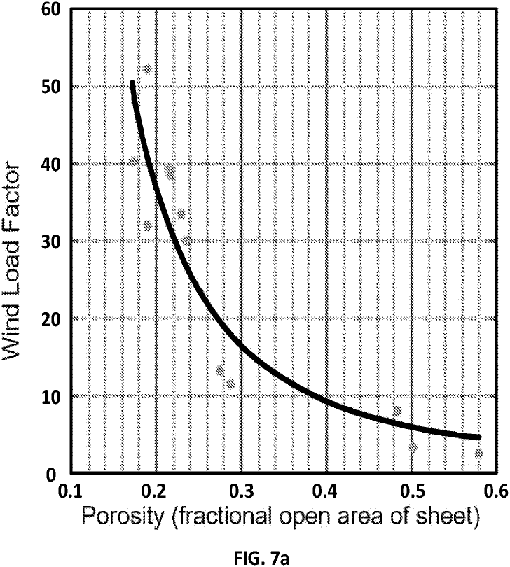

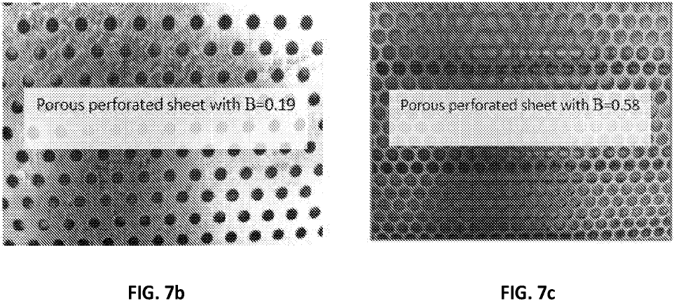

A number of wind tunnel studies conducted on porous plates (such as shown in FIGS. 7b and 7c) have shown a dramatic effect from porosity on reducing the wind load factor. For porous plates sealed in wind tunnels that force all air flow through the pores in the plate, the wind load factor decreases with the square of the porosity. This effect is shown in the graph of FIG. 7a of wind load factor versus porosity. Both the wind load factor and porosity are dimensionless quantities.

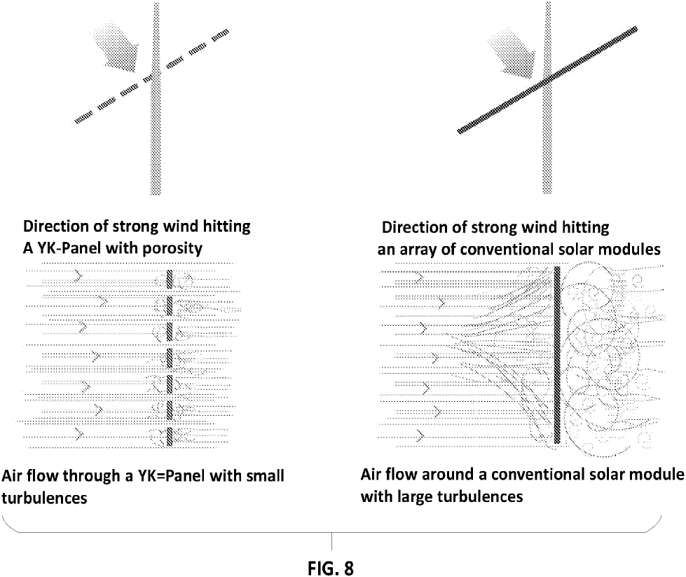

FIG. 8 illustrates the principle that porosity allows air to flow through a solar panel, limiting the turbulence behind the panel. Turbulence is a significant contributor to wind drag on an object.

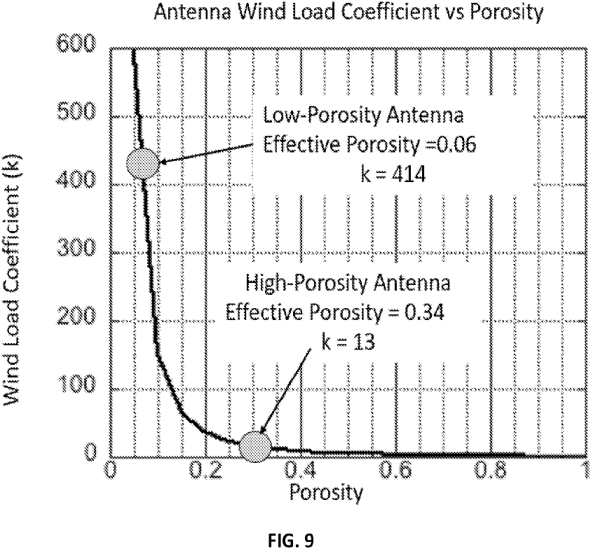

It can be assumed that a large plate such as a radar antenna that has many uniformly distributed holes through which air can pass is representative of the effect of wind loads on the YK-Panels described herein. FIG. 9 compares the wind load on such a radar antenna as a function of porosity of the antenna. From FIG. 9, it can be seen that wind load decreases sharply as porosity increases from 0% to about 30%. The wind load on such a body decreases slowly when the porosity of holes of the radar exceeds 30%. The decrease of wind load as a function of the antenna porosity depends on over-all porosity, but does not depend strongly on detailed shapes of the holes. Therefore, we can conclude from FIG. 9 that wind load on a YK-Panel will decrease sharply as the porosity of the YK-Panel is increased. Moreover, FIG. 9 shows that an optimal value of porosity of the YK-Panels described herein in the range of 10% to 30%.

If the percentage of empty gaps of the YK-Panels described herein is made larger than 30%, the mechanical/structural integrity of the aluminum frame may become too weak. The percentage of total area of empty gaps (% of porosity) of the YK-Panels described herein is in the range of 10% ~ 30%. The actual percentage of porosity of particular YK-Panels can be selected depending on the average wind speed and annual weather patterns of a geographic region where the particular YK-Panels will be installed.

The drastically lower wind load on YK-Panels compared to conventional solar panels allows YK-Panels to be installed several meters (3 meters or higher) above the ground.

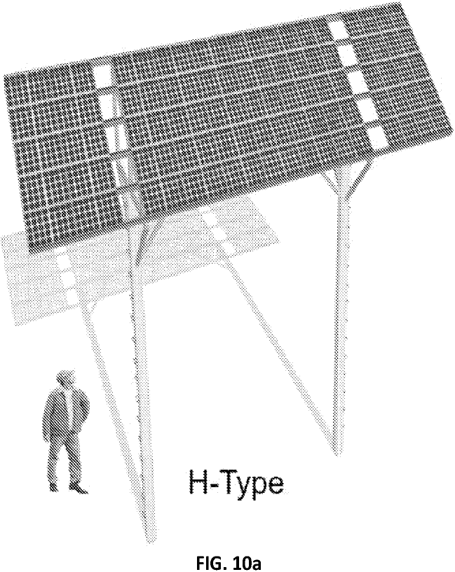

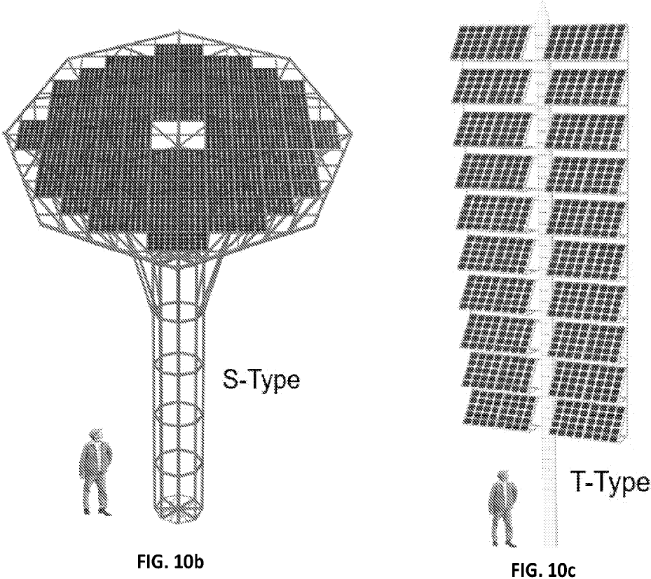

When the YK-Panels are installed sufficiently above ground level, people and/or vehicles can move around freely under the installed YK-Panels. This concept is depicted in FIGS. 10a-10c, for example. FIGS. 10a-10c show three different types of support structures which can hold and support arrays of YK-Panels high above the ground (e.g., at a height of 3 meters or higher). The three support structures are called H-Type HelioTower (FIG. 10a), S-Type HelioTower (FIG. 10b), and T-Type HelioTower (FIG. 10c).

It is difficult to install conventional large solar panels high above the ground (e.g., at a height of 3 meters or higher) due to the immense wind load on the conventional large solar panels in strong wind. It is anticipated that the wind load on a conventional solar panel of 2 meter-square of surface area may be about 30 times more than wind load on a YK-Panel of the same surface area in the same wind speed of about 30 meters per second.

The porosity of YK-Panels not only allows wind to pass through the YK-Panel, but it allows sunlight and rainwater to pass through the YK-Panel as well. This advantageously enables the construction of solar farms with HelioTowers of YK-Panels on economically active farmlands. The farmlands stay as economically productive farmlands, and at the same time are a solar farm to produce electricity from sunlight. That is, the land can be used doubly as farmland and as a solar farm. There are many millions of acres of farmlands in the US which are ideal places for construction of solar farms with H-Type or T-Type HelioTowers of YK-Panels. Construction of solar farms with H-Type or T-Type HelioTowers of YK-Panels will not damage the environment and ecology of the land.

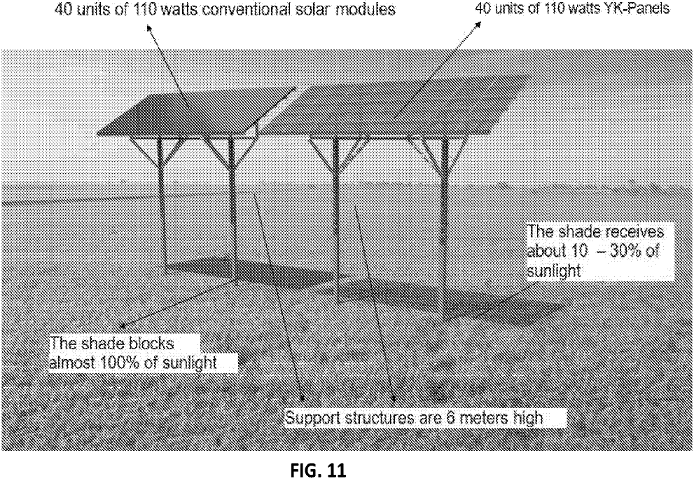

FIG. 11 shows the benefits to farmland by allowing sunlight and rainwater to pass through the YK-Panels. As shown on the left, traditional solar panels block nearly 100% of sunlight. As shown on the right, in some embodiments the H-Type HelioTower allows up to about 30% (e.g., at least 10%, at least 20%, about 10% to 30%, about 20% to 30%, or greater than 30%) of the sunlight to illuminate the ground under the HelioTower (because the open space of the YK-Panels equals those percentages of the total area of the YK-Panels). Rain will also pass through the YK-Panels to irrigate the ground.

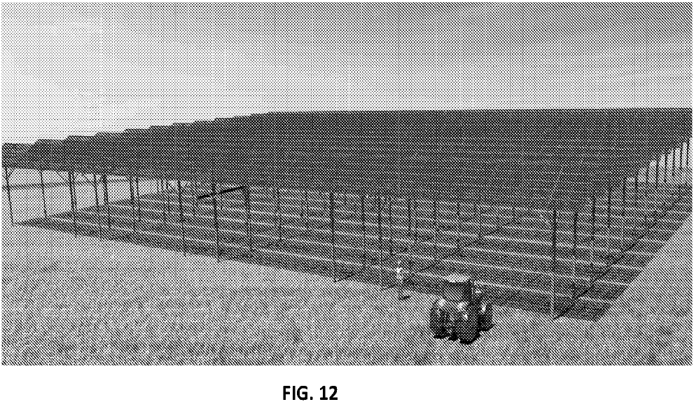

FIG. 12 shows a large solar farm of H-Type HelioTowers on flat green land. The YK-Panels reside high above the ground, allowing farming of the ground beneath the YK-Panels.

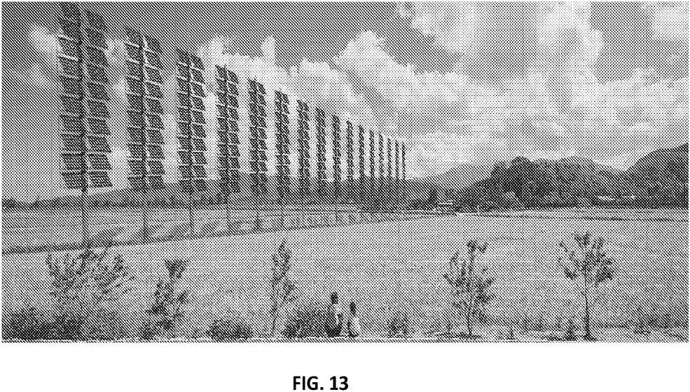

FIG. 13 shows that T-Type HelioTowers are also suitable for installation on agricultural land. In this example, the T-Type HelioTowers are installed along an edge of a field of rice.

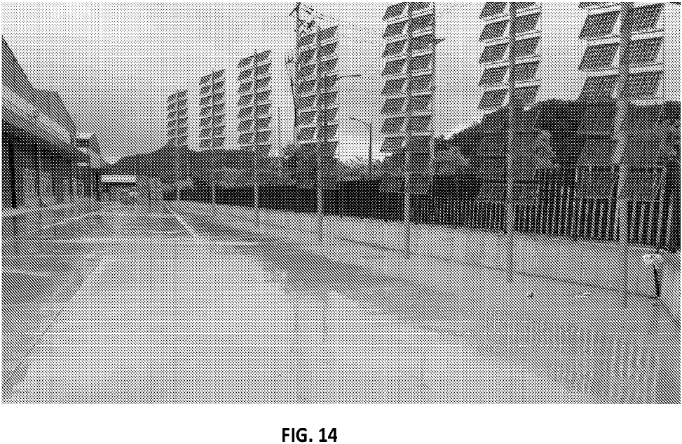

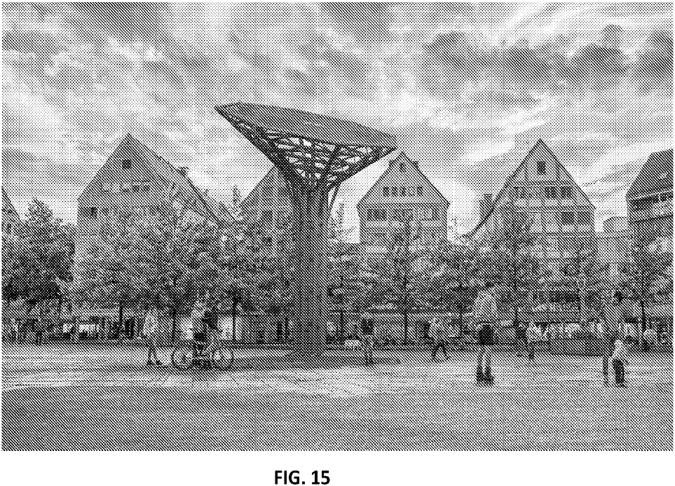

FIGS. 14 and 15 show that HelioTowers can enable dual use of industrial land and commercial spaces. In this way, the YK-Modules and HelioTowers described herein solve or mitigates both problems one and four described above. The large wind resistance of conventional solar panels prevents such installations.

The YK-Modules described herein also mitigate or solve the third problem (the high temperature of conventional solar cells). Temperatures of conventional solar panel rises high above ambient temperature under strong sunlight. Temperatures of YK-Modules under the same strong sunlight are significantly lower than conventional solar modules or solar panels. The surfaces of the YK-Modules are covered with heat-conductive aluminum (or metal alloy) except for the top sunlight receiving surface. In addition, there are empty gaps between neighboring YK-Modules in a YK-Panel. In some embodiments, YK-Module and YK-Panels are made of aluminum which has a very high thermal conductivity. This is because the aluminum removes heat of YK-Modules to the air far more efficiently that typical polymeric materials, such as Tedlar used for conventional solar panels. The empty gaps allow air pass through YK-Panel freely. Under strong sunlight, convective air flows through the empty gaps of YK-Panel remove heat from YK-Modules to the air highly efficiently. Conventional solar panels have no similar empty gaps and there is no convective air flow passing through conventional solar panels. In addition, the aluminum frames of the YK-Panels have a large surface area.

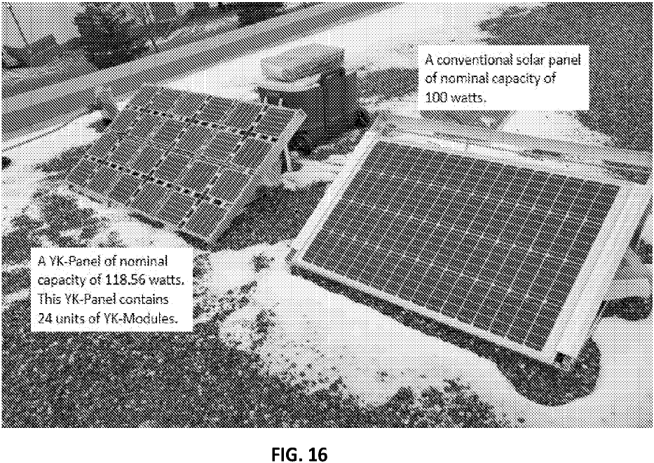

The combined effects of high thermal conductivity of the aluminum surfaces of the YK-Modules, the large surface area of aluminum frames of the YK-Panels, and the convective air flow through empty gaps on YK-Panel keep the temperature of YK-Module and YK-Panel significantly lower than the temperature on conventional solar panel under the same exposure to sunlight at the same ambient temperature. FIG. 16 shows an actual YK-Panel (on the left) side-by-side with a comparable conventional solar panel (on the right) on the roof of a building.

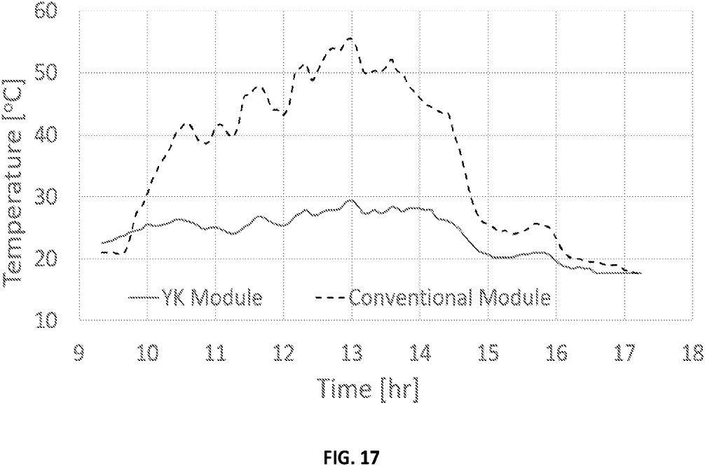

FIG. 17 shows the temperature profiles of the two panels of FIG. 16. This test was performed on a cold, sunny January day with ambient temperatures ranging from -6.7° C. to -2.0° C. As shown by the upper plotted line, significant heating of the conventional panel is seen even in cold weather. The excellent heat dissipation of the YK-Panel eliminates that heating is shown by the lower plotted line. This figure shows that the YK-Panel is 25° C. cooler than the conventional panel during peak illumination by sunlight. Accordingly, it can be seen that the unique features of YK-Modules and YK-Panels can solve problem three described above.

In some embodiments, the YK-Modules and YK-Panels described herein can mitigate problem two described above by using recyclable materials. For example, the YK-Modules can be covered by aluminum sheet (or metal alloy sheet) entirely except its sunlight-receiving surface. In some embodiments, the YK-Panel has a 100% aluminum (or metal alloys) frame which holds a number of YK-Modules which are electrically connected. The aluminum of YK-Modules and YK-Panels are easily recovered or recycled after the service life of the YK-Modules and/or YK-Panels.

The top sunlight-receiving surface of a YK-Module is covered with solar glass plate. The glass plate is only slightly larger than typical size of a photovoltaic silicon wafer. The glass plates on each of YK-Modules can be easily removed from expired YK-Modules. The glass plates can be cleaned and reused for YK-Modules again. Therefore, most of the materials of the YK-Modules and YK-Panels (which are aluminum and solar glass plates, for example) can be easily recycled or reused. Therefore YK-Modules and YK-Panels will not create huge amounts of solid wastes like expired conventional solar panels. In this way, the YK-Modules and YK-Panels described herein solve or mitigate problem two described above.

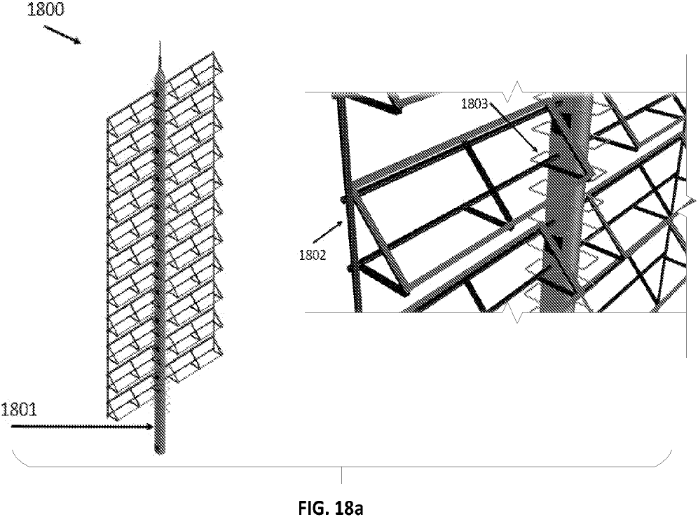

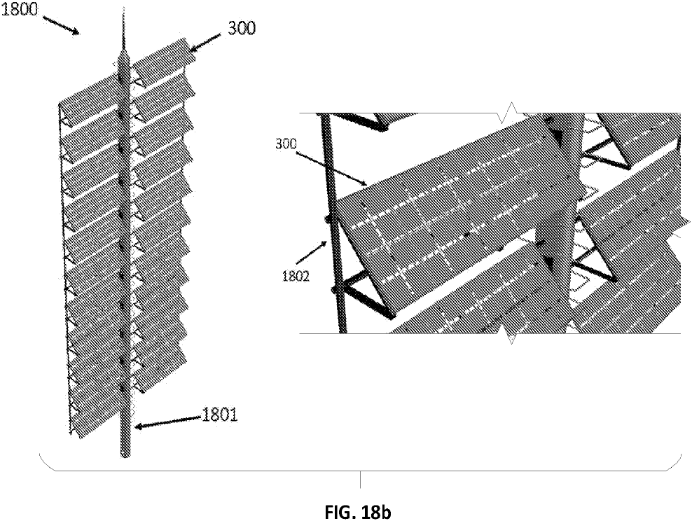

The YK-Panel shown in FIGS. 1 through 3 needs to be mounted on a scaffold or some type of super-structure that will hold a plurality of YK-Panels in order to produce sufficient electrical power to be supplied to an electrical grid or other useful electrical load. One such scaffold or super-structure is the aforementioned T-Type HelioTower that can be especially useful in both agricultural and industrial settings (e.g., see FIGS. 13 and 14). A preferred embodiment of the T-Type HelioTower is shown in FIGS. 18a and 18b. FIG. 18a shows the skeleton structure of a T-Type HelioTower 1800 with center support pole 1801 and the support brackets 1802. The example also shows an integral ladder that enables maintenance of the T-Type HelioTower and YK-Panels on an installed unit.

The devices, systems, materials, compounds, compositions, articles, and methods described herein may be understood by reference to the above detailed description of specific aspects of the disclosed subject matter. It is to be understood, however, that the aspects described above are not limited to specific devices, systems, methods, or specific agents, as such may vary. It is also to be understood that the terminology used herein is for the purpose of describing particular aspects only and is not intended to be limiting.

A number of embodiments have been described. Nevertheless, it will be understood that various modifications may be made without departing from the claim scope here. Accordingly, other embodiments are within the scope of the following claims.

1. A solar panel system (“YK-Panel”) configured to convert sunlight to electrical energy, the YK-Panel comprising:
two or more YK-Modules, wherein each YK-Module of the two or more YK-Modules comprises:
a tray comprising a heat-conductive substrate; and
a solar cell assembly contained within the tray and comprising: (i) a solar cell, (ii) an encapsulant, and (iii) a transparent cover, wherein the solar cell is contained within the encapsulant, wherein a bottom surface of the encapsulant faces the tray and a top surface of the encapsulant faces the cover; and
a frame assembly attached to each tray of the two or more YK-Modules to provide structural support to the two or more YK-Modules,
wherein open space is defined between adjacent YK-Modules of the two or more YK-Modules.

2. The YK-Panel of claim 1, wherein the open space totals at least 10% of a total area of the YK-Panel.

3. The YK-Panel of claim 1, wherein the open space totals at least 20% of a total area of the YK-Panel.

4. The YK-Panel of claim 1, wherein the open space totals 10% to 30% of a total area of the YK-Panel.

5. The YK-Panel of claim 1, further comprising one or more interconnectors extending laterally from each tray of the two or more YK-Modules, the one or more interconnectors connecting adjacent trays of the two or more YK-Modules.

6. The YK-Panel of claim 1, wherein the frame comprises multiple ribs that interlock with each other and with the two or more YK-Modules.

7. The YK-Panel of claim 6, wherein the multiple ribs include tabs that extend through respective slots defined by each tray of two or more YK-Modules.

8-10. (canceled)

11. An assembly of one or more solar YK-Modules comprised of a heat-conductive substrate attached to a heat-conductive frame to form a YK-Panel;
wherein the heat-conductive substrate supports one or more solar cells capable of converting sunlight to electricity while isolated from UV radiation, humidity, and oxygen by an encapsulant;
wherein sunlight illuminated sides of the solar cells are covered by a transparent cover;
wherein the solar cells are separated from the substrate by an electrical insulator;
wherein the YK-Modules are attached to the frame such that each of the one or more YK-Modules is separated from adjacent YK-Modules by empty gaps; and
wherein the YK-Modules are electrically interconnected to form a circuit that can drive an external electrical load.

12. The assembly of claim 11, wherein the substrate is aluminum, copper, or stainless steel.

13. (canceled)

14. (canceled)

15. The assembly of claim 11, wherein the substrate is a ceramic-filled polymer.

16. The assembly of claim 15, wherein the ceramic-filled polymer comprises aluminum nitride, boron nitride, or polyester.

17. (canceled)

18. (canceled)

19. The assembly of claim 11, wherein the frame is aluminum, copper, or stainless steel.

20. (canceled)

21. (canceled)

22. The assembly of claim 11, wherein the frame is a ceramic-filled polymer.

23. The assembly of claim 22, wherein the ceramic-filled polymer comprises aluminum nitride, boron nitride, or polyester.

24. (canceled)

25. (canceled)

26. The assembly of claim 11, wherein the solar cell comprises crystal silicon, CdTe, or perovskite.

27. (canceled)

28. (canceled)

29. The assembly of claim 11, wherein the encapsulant is ethyl vinyl acetate, or silicone rubber.

30. (canceled)

31. The assembly of claim 11, wherein the cover is a solar glass or polycarbonate.

32. (canceled)

33. The assembly of claim 11, wherein the electrical insulator is fiberglass, nylon, or a polyimide.

34. (canceled)

35. The assembly of claim 11, wherein the electrical insulator is a ceramic-filled polymer.

36. The assembly of claim 35, wherein the ceramic-filled polymer comprises aluminum nitride, boron nitride, or polyester.

37-39. (canceled)

40. The assembly of claim 11, wherein the empty gaps permit the flow of air, rainwater, and sunlight in a direction substantially perpendicular to the plane of the YK-Panel.

41. (canceled)
